(19) United States
(12) Patent Application Publication
(10) Pub. No.: US 2023/0359784 A1
(43) Pub. Date: Nov. 9, 2023

(54) METHOD AND DEVICE FOR CONFIGURING A MODULE FOR SIMULATING AT LEAST ONE SENSOR

(71) Applicant: dSPACE GmbH, Paderborn (DE)

(72) Inventors: Gregor SIEVERS, Paderborn (DE); Johannes AX, Paderborn (DE)

(73) Assignee: dSPACE GmbH, Paderborn (DE)

(21) Appl. No.: 18/129,453

(22) Filed: Mar. 31, 2023

(30) Foreign Application Priority Data
May 3, 2022 (DE) 10 2022 110 843.0

(51) Int. Cl. G06F 30/20

(52) U.S. Cl. CPC G06F 30/20

(57) ABSTRACT

A method for configuring a module for simulating at least one sensor, wherein the sensor simulation is designed and set up to supply synthetic sensor data to a device for executing open- and/or closed-loop tasks via the first data interface of the first type. The method has the steps: a) Receiving a record of a data exchange of a real sensor with the device and/or receiving information about at least one property of the real sensor and/or the second data interface of the first type, b) Reading out the record and/or the information about the at least one property, c) Determining at least one characteristic of the real sensor and/or the second data interface, d) Configuring the sensor simulation and/or the first data interface of the first type using the at least one characteristic such that the synthetic sensor data simulate the sensor data of the real sensor.

This nonprovisional application claims priority under 35 U.S.C. § 119(a) to German Patent Application No. 10 2022 110 843.0, which was filed in Germany on May 3, 2022, and which is herein incorporated by reference.

### BACKGROUND OF THE INVENTION

### Field of the Invention

The present invention relates to a method and to a device for configuring a module for simulating at least one sensor. The application further relates to a module for simulating at least one sensor and to a device for executing open- and/or closed-loop tasks, in particular for a vehicle.

### Description of the Background Art

Devices for executing open- and/or closed-loop tasks in vehicles are also referred to as control units. Control units in vehicles, in particular motor vehicles, can have a computing unit, memory, interfaces, and possibly other components, which are required for processing input signals with input data in the control unit and for generating control signals with output data. The interfaces are used to receive the input signals or to output the control signals.

Control units for driving functions, both for advanced driver assistance systems (ADAS) and for autonomous or semi-autonomous driving, can receive sensor data from various sensors as input data.

One way of testing control units that evaluate sensor data from sensors is to test the control units with the corresponding sensors in the installed state, for example, in a motor vehicle during test drives. This is time-consuming and cost-intensive, and many situations cannot be assessed in a real environment because they only occur in extreme cases, for example, in accidents. For this reason, such control units are tested in artificial environments, for example, in test benches. A further common test scenario here is to test the functionality of a control unit using a simulated environment. In this case, the environment simulation can comprise the simulation of real sensors by means of a sensor simulation. The sensor simulation can generate synthetic sensor data that reproduce the virtual environment of the control unit.

Rapid Control Prototyping (RCP for short) refers to a computer-aided design method for rapid open- and closed-loop development, especially also for control units in vehicles. Design steps in RCP comprise prototypes of different design stages of a control unit function, which in turn can be tested in conjunction with the environment or with an environment simulation. Typical design steps in RCP comprise the (dynamic) description of the system to be automated and its modeling, the open- and control-loop design in the model.

A further method for testing control units is the so-called hardware-in-the-loop (HIL for short) test, wherein the open- and closed-loop design is finally implemented in the control unit and the solution is tested in a pure simulation environment but on a real system.

In a so-called software-in-the-loop (SIL for short) test, a real control unit is not yet used. Here, the software code of the open- and closed-loop design is tested on a simulator, e.g., on a suitably equipped PC, in interaction with a so-called environment model.

An HIL environment that replaces and simulates a camera image sensor including a lens is described in “Sensor-realistic simulation in real time”, Caius Seiger, Dr. Gregor Sievers, HANSER Automotive 7/2020. The raw sensor data are transferred to an environmental sensor interface unit (ESI unit) via a DisplayPort interface of a GPU (graphics processing unit). The ESI unit is an FPGA-based platform on which model-based sensors are simulated. Further components of the sensor models, e.g., a simulation of the I2C interface of the camera image sensor, are executed on the ESI unit.

No manufacturer-independent interface standard has emerged thus far for the transmission of raw sensor data. Therefore, a test system for raw sensor data ingestion must support a variety of sensor interfaces, which must be configured accordingly.

The use of the ESI unit for raw data simulation is described in “Sensor simulation in in-the-loop environments” Holger Krumm, ATZ 2019, wherein a variety of interfaces are supported, which comprise long-haul interfaces, short-haul interfaces, and the I2C control channel.

Due to a large number of sensors with a large number of configuration options, a high effort of manual adjustment (engineering) may therefore be required. The present invention is thereby intended to improve the configuration.

### SUMMARY OF THE INVENTION

It is therefore an object of the present invention to provide a method for configuring a module for simulating at least one sensor, the module has a sensor simulation and a first data interface of a first type, wherein the sensor simulation is designed and set up to supply synthetic sensor data to a device for executing open- and/or closed-loop tasks via the first data interface of the first type.

The method can include the step of receiving a record of a data exchange of a real sensor with the device, wherein the data exchange took place via a second data interface of the first type, and/or receiving information about at least one property of the real sensor and/or the second data interface of the first type.

A property of the second data interfaces of the first type may have, e.g., a property of a protocol. For example, the protocol can relate to a communication protocol according to the rules of which the data exchange takes place via the second data interface of the first type.

The record, e.g., a log file, can be received thereby in particular by a device for configuring the module for simulation. The device can be designed, e.g., as a PC with executable software which reads in the log file. The PC can be connected, e.g., to one module for simulation or multiple modules for simulation, therefore, e.g., be communicatively connected.

The information about the at least one property of the real sensor and/or the second data interface of the first type can be contained, e.g., in a configuration specification which is assigned, e.g., to the real sensor and/or the device for executing open- and/or closed-loop tasks. The information about the at least one property can be information, in particular additional information about the real sensor, e.g., type, type of interface, information, which information, e.g., for an imager, is in which register, etc., and/or further information about the second data interface of the first type, e.g., about the protocol. The properties for the second data interface of the first type may comprise properties for the protocol of the data interface, therefore, in particular further information about the protocol.

The method can also include the step of reading out the record and/or the information about the at least one property. For example, a linking of the read-out record with the received information about the at least one property can take place in this step.

Here, e.g., parsing of the record by the device can correspond to reading out the record. This can also be referred to as reading in the record by the device. The record can be, e.g., a log file with a specified format. It can be read in by the configuration program and, e.g., stored in a database. In this step, moreover, enrichment can be performed with the information about the at least one property, therefore, with further information, such as, e.g., information about the sensor type of the real sensor.

The information about the at least one property can be determined by receiving and reading out the configuration specification and optionally incorporated into the database. It can then be reused, e.g., for further configuration operations or further modules for simulation. In particular, the read-out record linked to the information about the at least one property can be stored in the database and then reused or repurposed.

The log file contains data, in particular, on write and read accesses via the interface of the first type, therefore, in particular at which point access was made and what information was taken from there. The kind of data that the transmitted data of the record are and where they can be found in the record can be determined on the basis of, e.g., the information about the sensor type (property).

The reading out includes a parsing of the data contained in the record based on the properties, therefore, e.g., with the aid of the device information, which is usually supplied in addition to the real sensor and/or control unit. This is, e.g., information about the device type of the real sensor (e.g., information on which information for an imager is in which register).

The method can also determine at least one characteristic of the real sensor and/or the second data interface of the first type, and the method can include the step of configuring the sensor simulation and/or the first data interface of the first type based on the at least one characteristic such that the synthetic sensor data simulate the sensor data of the real sensor.

The step of determining the at least one characteristic of the real sensor and/or the second data interface of the first type can be carried out on the basis of the read-out record and/or information stored in the database.

The described method can thus improve the handling of the configuration of sensors and, in particular, it can be made possible that the module can configure itself substantially independently, therefore, e.g., set itself to an executable state in an automated or semi-automated manner.

Synthetic sensor data can be data output by the sensor simulation to simulate a real sensor, e.g., an environmental sensor, such as, e.g., a camera sensor, a radar sensor, a lidar sensor, an ultrasonic sensor, and/or an infrared sensor. The synthetic sensor data can be completely or partially generated by the sensor simulation. In case of a complete generation by the sensor simulation, the sensor data are generated, e.g., by the environment model. In the case of a partial generation by the sensor simulation, it can be, for example, previously recorded sensor data, in particular real recorded sensor data, which are modified by the sensor simulation, therefore, e.g., adapted and/or supplemented, etc., so that they correspond (better), e.g., to the sensor data of the real sensor.

The device for executing open- and/or closed-loop tasks can be designed in this case as a control unit or correspond to a design stage of the prototype development, which in turn, depending on the stage, can be designed as a pure software simulation. Accordingly, the method can be used both for hardware-in-the-loop systems and software-in-the-loop systems.

The record of the data exchange of a real sensor with the device is in particular a so-called log file of the data exchanged between the real sensor and the device via the corresponding communication link via the second data interface of the first type. The communication link is usually used to exchange both sensor data and configuration data for the data interface of the first type. The power supply for the sensor can optionally be realized via the same connection as the communication, e.g., PoC (power over coax).

The first and second data interfaces of the first type can be designed and set up for data exchange using the same protocol, in particular the communication protocol. The first and second data interfaces may also have, e.g., substantially the same hardware equipment, therefore, e.g., be realized with the same type of chip, connector, etc. In this case, the characteristic determined in the method can in particular concern a parameter of the protocol of the data interface of the first type, which is adapted by the method. For the data interfaces, there are various configuration options, such as, e.g., data rates, sensor interfaces, etc., e.g., on the part of the manufacturers. When the device is connected to the real sensor, the sensor and/or the second data interface of the first type can be configured via the communication link between the device and the real sensor. Therefore, by recording and reading out this communication, at least one characteristic can be obtained and the first data interface of the first type can be configured accordingly in the sensor simulation. This saves manual configuration in particular. The sensor simulation can therefore be adapted to the device more easily, reliably, and quickly.

The communication link via the first and second data interfaces of the first type can be designed, e.g., as a serial data link, in which the data are serialized in the first and second data interfaces of the first type by a serializer and are deserialized again in a data interface of the second type, e.g., located in the device, e.g., by a deserializer. Such an interface enables a certain distance between the device and the sensor or sensor simulation, which can then be overcome, e.g., via a connection using a coaxial cable. Possible protocols that can be used are, e.g., LVDS-Link, FPD-Link III, GMSL, MIPI A-PHY, MIPI D-PHY, ASA Motionlink, Ethernet, I2C, SPI, and UART. Optionally, in step c), a characteristic of the interface of the second type can also be determined, and optionally, in step d), the interface of the second type can also be configured.

The data interface of the first type can also be designed as a pure hardware interface or electrical interface, which can be realized, e.g., directly on the chip. This is advantageous for realizations of sensor/sensor simulation in spatial proximity to the device, e.g., in the same housing.

The at least one characteristic can be determined by reading out the record based on at least one property of the protocol, the real sensor, and/or the second data interface of the first type. The determination based on this property or these properties makes use of the fact that, with knowledge of the protocol used for the record for data exchange via the second data interface of the first type, the sensor used for the record, and/or the second data interface of the first type used for the record, it is also known (e.g., from the received information about the at least one property) where in the record which information can be found, which can then be used as the characteristic or characteristics to configure the sensor simulation and/or the first data interface of the first type. For example, a designation of the protocol and/or information about the type of protocol can serve as a search and/or decision criterion to determine the characteristic from the record and/or the database.

The sensor simulation and/or the first data interface of the first type can be configured by writing at least one register of the module, wherein the written content of the register depends in particular on the at least one characteristic, and wherein the selection of the register and the way it is described depend in particular on the at least one property. The configuration therefore takes place in particular in that the configuration takes place with the characteristic, and the location of the register and the format of the writing are determined on the basis of the at least one property.

A code, in particular an executable program code and/or an executable configuration file, can be generated which, when executed, is suitable for carrying out the configuration. The generation of the code can also be the parameterization of an already existing configuration file (even only in parts) or an already existing configuration code. This enables further automation of the configuration process. Alternatively or in addition, the configuration can also be performed according to the invention via Ethernet (e.g., XCP, XIL-API) or similar methods.

A database can be accessed to determine the at least one characteristic and the code is generated depending on a data content provided by the database, wherein the data content provided by the database depends on the at least one property. This embodiment makes it possible to obtain the at least one characteristic that can depend on the at least one property and can be used not only directly by reading out the record, but also to enable obtaining it by reading entries of the database. E.g., receiving the information about the property or properties of the real sensor and/or the second data interface of the first type can be done by accessing the database where this information has been stored.

A database is accessed to generate the code and the code is generated depending on a further data content provided by the database, wherein the further data content provided by the database depends on the at least one property. This example makes it possible to obtain knowledge that depends on the at least one property and that can be used not only directly by reading out the record, but also to enable obtaining it by reading entries of the database. Alternatively or in addition, code generation can be accelerated by using entries in the database.

The data content can be, e.g., a temperature value. The further data content can be information supplementing the data content, therefore, related to the temperature value, e.g., the information about the format in which the temperature value is stored and/or optionally that this concerns a temperature value.

For code generation, it can be possible for a user of the module to manually make changes and/or additions to the code before the code is brought to execution for the purpose of configuration. For such applications, an example provides, in a method step, writing a data content in the database using the at least one property such that it is suitable to be provided by the database depending on the at least one property. This enables a continuous improvement of the database content.

In this regard, the at least one characteristic with which the sensor simulation and/or the data interface of the first type are configured relates, e.g., to an image resolution and/or a color space of the sensor simulation for a camera sensor and/or a generation of statistics for the synthetic image data of a camera sensor output by the sensor simulation. In particular, the generation of statistics can relate to the generation of a histogram by an imager, therefore, a camera sensor. Here, a histogram of the color/pixel values for each image sent from the sensor is calculated in the imager and attached to each image as an additional image line as so-called embedded statistics. This function is usually disabled by default, but can be enabled by configuring the sensor, e.g., by a command via an I2C interface. By the proposed method, this characteristic “histogram generation enabled” can be read out from the record and the sensor simulation can be configured accordingly in that histogram generation is enabled in the sensor simulation as well.

Further examples of the at least one characteristic relate to the temperature of the sensor, the frame counter, therefore, a running counter for each image of a camera sensor, the frame rate, therefore, e.g., the number of images per second, and/or checksums for parts or the entire image of a camera sensor.

A module for simulating at least one sensor has hardware and software for a sensor simulation and a data interface of the first type, wherein the sensor simulation is designed and set up to supply synthetic sensor data to a device for executing open- and/or closed-loop tasks via the first data interface of the first type.

A device for configuring the module for simulation can be a computing unit for executing a configuration program. The configuration program is designed in particular as software with program instructions. When the program instructions are executed, the previously described method is executed. Thus, e.g., this is a PC, which can be connected with the module, e.g., an ESI unit (ESI environmental sensor unit), or also multiple modules. It can also be provided to run the configuration program on the module. The device for configuring the module for simulating at least one sensor is set up and designed: to receive a record of a data exchange of a real sensor with the control unit, wherein the data exchange took place via a second data interface of the first type, and/or to receive information about the at least one property of the real sensor and/or the second data interface of the first type, to read out the record and/or the information about the at least one property, to determine at least one characteristic of the real sensor and/or the second data interface of the first type, and to configure the sensor simulation and/or the first data interface of the first type using the at least one characteristic such that the synthetic sensor data simulate the sensor data of the real sensor.

The device for executing open- and/or closed-loop tasks can be designed as a control unit and/or as a device for simulating a control unit. In particular, the device can embody different stages of functional and hardware development of a control unit.

The device can be configured and set up to generate a code, in particular an executable program code and/or an executable configuration file, and to perform the configuration by executing the code. For this purpose, the device has a computing unit with a corresponding memory and corresponding interfaces and is equipped with a corresponding configuration program.

The device can be designed and set up to access a database to determine the at least one characteristic, wherein the device is designed and set up to determine the at least one characteristic depending on a data content provided by the database, wherein the data content provided by the database depends on a property of the protocol, the real sensor, and/or the second data interface of the first type.

The device can be designed and set up to access a database to generate the code, in particular the executable program code and/or the executable configuration file, wherein the device is designed and set up to generate the code depending on a further data content provided by the database, wherein the further data content provided by the database depends on the property of the protocol, the real sensor, and/or the second data interface of the first type.

The device can have a memory with the database and/or the device has a communication interface for accessing the database. The database can thus be designed, e.g., as a memory region of the device or as an external database. The external database is accessed, e.g., via an interface. The database can also be located at a location remote from the device and the access occurs via remote data communication. Mixed forms of a so-called internal and so-called external database are also possible. A separation can occur here, e.g., according to the frequency of access.

An arrangement for simulating at least one sensor can have a module for simulating at least one sensor and a device described previously. The device can be part of the module or communicatively connected to it.

The synthetic sensor data generated by the module can simulate sensor data from a camera sensor, a radar sensor, a lidar sensor, an ultrasonic sensor, and/or an infrared sensor. In exemplary embodiments of the module, the sensor simulation is thus designed to simulate a camera sensor, also called an image sensor, a radar sensor, a lidar sensor, an ultrasonic sensor, and/or an infrared sensor.

The device can have a previously described module for performing open- and/or closed-loop tasks. In this example, the communication between the module and the device can take place via the first data interface of the first type, which can be designed, e.g., as a hardware interface.

The device for executing open- and/or closed-loop tasks can have a data interface of a second type for receiving synthetic sensor data from a previously described module. The data interface of the second type can be designed, e.g., as a deserializer. The data interface of the second type can be configured in an analogous manner as the sensor simulation and/or the first data interface of the first type by the method described previously. In particular, at least one characteristic for configuring the data interface of the second type can be determined from the record. It is also possible that at least one characteristic of the data interface of the second type can be determined from the record, which can then be used to configure the first data interface of the first type.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows a method for configuration;

FIG. 2 shows a schematic representation of an example of an arrangement with a device for configuration;

FIG. 3 shows a schematic representation of an example of an arrangement with a device for configuration;

FIG. 4 schematically shows an example of a method for configuration.

### DETAILED DESCRIPTION

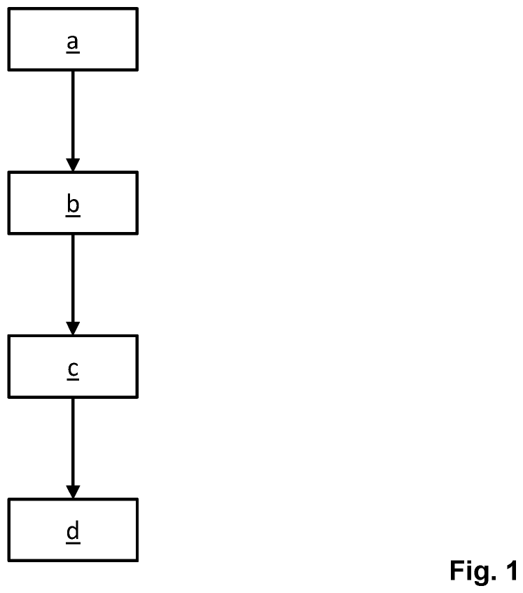

FIG. 1 schematically shows a method for configuring a module for simulating 12 at least one sensor. The method can include: (a) Receiving a record 20 of a data exchange of a real sensor 22 with a device 30 for executing open- and/or closed-loop tasks, wherein the data exchange occurred via a second data interface 24 of a first type; and/or receiving information about at least one property of real sensor 22 and/or the second data interface of the first type 24; (b) Reading out record 20 and/or the information about the at least one property. Optionally, the read-out record is linked to the received information about the at least one property; (c) Determining at least one characteristic Ch of real sensor 22 and/or the second data interface of the first type 24; and (d) Configuring a sensor simulation 16 of module 12 and/or a first data interface of the first type 14 of module 12 based on the at least one characteristic Ch.

The sensor simulation 16 of module 12 supplies device 30 with synthetic sensor data for executing open- and/or closed-loop tasks via the first data interface of the first type 14. The configuration in step d) takes place such that the synthetic sensor data simulate the sensor data of real sensor 22. This means that device 30 receives the synthetic sensor data from module 12 and processes them in the same way and responds to them in the same way as to sensor data from the real sensor.

The information about the at least one property of the real sensor and/or the second data interface of the first type can be contained, e.g., in a configuration specification which is assigned, e.g., to the real sensor and/or the device for executing open- and/or closed-loop tasks. It is possible to store at least parts of the record read out in step b) and/or information received about the at least one property in a database DB. The determination of the at least one characteristic Ch in step c) can then be performed based on the read-out record and/or received information about the at least one property and/or based on the corresponding data DB previously stored in the database.

It is conceivable to execute the configuration in step d) by executing software instructions of a program code. This program code can be automatically generated using the at least one characteristic Ch or automatically parameterized in the case of a configuration file. In this context, the characteristic Ch relates to configuration options, therefore, setting options, of the second interface of the first type 24 and/or of real sensor 22. In particular, the code can be generated using data contents of the database DB. In particular, the database DB can be accessed based on a property of the second interface of the first type, e.g., protocol, chip used, etc., and/or a property of real sensor 22, e.g., sensor type, manufacturer, etc. In this context, the property relates in particular to the kind or type of the second data interface of the first type 24 and/or real sensor 22, and the characteristic relates in particular to which configuration, therefore, setting, is to be made for specific setting options for such an interface of the first type 24 and/or such a sensor 22.

Module 12 configured with the automatically generated code can then be connected to device 30 for testing and the quality of the configuration can thus be determined. If the result is still not satisfactory, e.g., the automatically generated code can be adapted accordingly and module 12 can be reconfigured by executing the modified code. The reconfigured module 12 can then be reconnected to device 30, and the quality of the configuration can be checked using the synthetic sensor data provided by module 12. The configuration and the code that is executed for the configuration can be improved incrementally by such an iterative process. The modified code can then be saved back to the database DB.

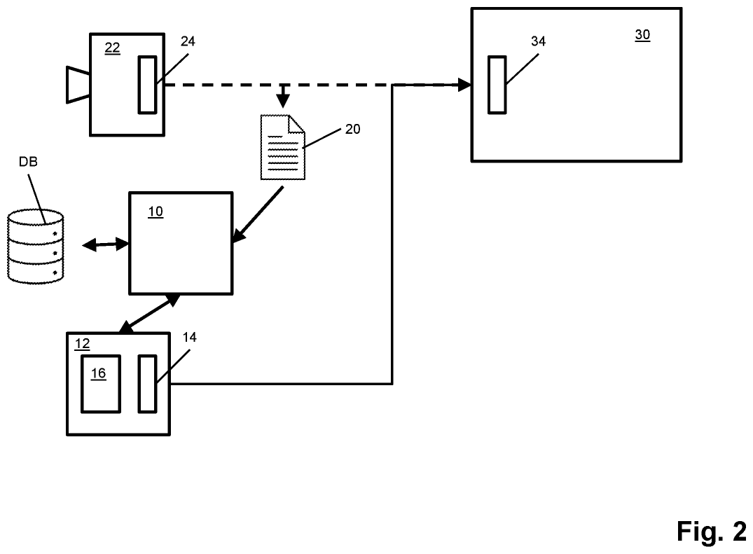

An example of an arrangement for configuring module 12 for simulating at least one sensor with the device for configuring 10 module 12 for simulation is shown in FIG. 2. Module 12 has hardware and software for sensor simulation 16 and the first data interface of the first type 14, which can be formed in particular as a serializer. Sensor simulation 16 is designed and set up to supply synthetic sensor data to device 30 for executing open- and/or closed-loop tasks via the first data interface of the first type 14. For this purpose, the sensor simulation outputs the synthetic sensor data via the first interface of the first type 24. Device 30 can be designed as a control unit and/or as a device for simulating a control unit. It receives the synthetic sensor data via the data interface of the second type 34, which can be designed in particular as a deserializer.

The connection of real sensor 22 to device 30 is shown by the dashed line in FIG. 2. The data exchange of real sensor 22 with device 30 takes place via this connection, which can be made, e.g., by a cable such as a coaxial cable. In this case, real sensor 22 outputs sensor data via the second interface of the first type 24, e.g., a serializer. The sensor data are received by device 30 via the interface of the second type 34, e.g., a deserializer. Such a data exchange of real sensor 22 with device 30 is recorded and record 20 is transmitted to device 10. Such a record 20 can be made, e.g., directly via a log file and/or via a special interface, e.g., debug interface, of device 30 and/or sensor 22. For record 20, the data can be recorded or tapped, for example, at the second interface of the first type 24 or at the interface of the second type 34 or, as indicated in FIG. 2, via an interface in the connection between sensor 22 and device 30. Such a record according to step a) of the method does not have to be repeated for each configuration process. The record and/or the configuration specification can be read in only once and then used for multiple chronologically consecutive tests or for multiple parallel tests of control units of the same type and configuration.

Device 10 is set up and designed to read record 20, to determine the at least one characteristic Ch of real sensor 22 and/or the second data interface of the first type 24 from the record, and to configure sensor simulation 16 and/or the first data interface of the first type 14 using the at least one characteristic Ch such that the synthetic sensor data simulate the sensor data of real sensor 22. This takes advantage of the fact that the first and second data interfaces 14, 24 are of the same type. Module 12 is intended to simulate real sensor 22 as precisely as possible, so that record 20 is used for the configuration in order to provide device 30 with synthetic sensor data that is as close as possible to, and preferably nearly identical to, the real sensor data of real sensor 22.

The hardware for sensor simulation 16 can be designed, e.g., as an FPGA board which is programmed by means of the software for sensor simulation 16. A GPU (graphics processing unit), in which, e.g., the color output is configured, can also be used as hardware for sensor simulation 16. Device 10 is designed and set up to generate a code and to perform the configuration by executing the code, wherein a database DB containing data for the interfaces and the at least one sensor and other components is accessed to generate the code.

Device 10 can have a memory containing the database DB and/or device 10 can have a communication interface for accessing the database DB. In particular, the database can be provided as a central database in the so-called “data cloud” or a central office, for access by a number of devices 10.

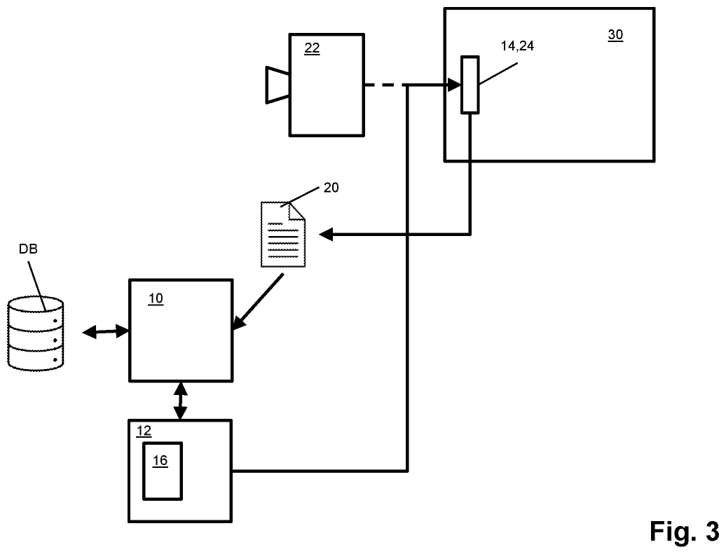

A further example of an arrangement for configuring module 12 for simulating at least one sensor with the device for configuring 10 module 12 for simulation is shown in FIG. 3. Module 12 has hardware and software for sensor simulation 16 and the first data interface of the first type 14. In the example shown in FIG. 3, the first data interface of the first type 14 is located in device 30 and is identical to the second data interface of the first type 24.

Sensor simulation 16 is designed and set up to supply synthetic sensor data to device 30 for executing open- and/or closed-loop tasks via the first data interface of the first type 14, 24. For this purpose, the sensor simulation outputs the synthetic sensor data via the first interface of the first type 14. Device 30 can be designed as a control unit and/or as a device for simulating a control unit. It receives the synthetic sensor data via the first data interface of first type 14, 24. Optionally, module 12 can be located in device 30 and can be located, e.g., in the same housing.

In this example, device 30 does not have a data interface of the second type. The data interface of the first type 14, 24 is designed, e.g., as a hardware interface with, e.g., a plug connection.

Sensor data is received from real sensor 22 via the one data interface of the first type 14, 24, which is shown with the dashed line in FIG. 3. During operation with real sensor 22, real sensor 22 can be directly connected to device 30 via the data interface of the first type 14, 24 and can optionally be integrated into device 30. The data exchange of real sensor 22 with device 30 takes place via this connection. Such a data exchange of real sensor 22 with device 30 is recorded and record 20 is transmitted to device 10.

Device 10 is set up and designed to read out record 20, to determine the at least one characteristic Ch of real sensor 22 from the record, and to configure sensor simulation 16 using the at least one characteristic Ch such that the synthetic sensor data simulate the sensor data of real sensor 22. In this example, the configuration of the first and second data interfaces 14, 24 can be omitted because they are the same data interface of the first type 14, 24.

Sensor simulation 16 of module 12 is set up to simulate sensor data of a camera sensor, a radar sensor, a lidar sensor, an ultrasonic sensor, and/or an infrared sensor and to output them as synthetic sensor data.

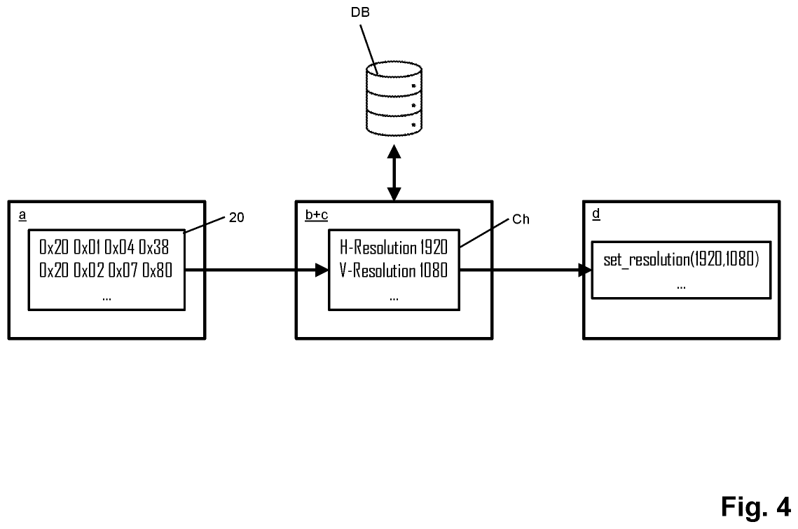

FIG. 4 schematically shows an example of a method for configuration using an automatically generated code.

In the example shown, record 20 is an I2C log with two accesses with device address 0x20 to an imager, therefore, a camera sensor. Register 0x01 is accessed once and register 0x02 is accessed once. Record 20 is read out in step b) and automatically analyzed in step c). In the example shown, this results in I2C accesses to two registers of the horizontal (0x07, 0x08) and vertical image resolution (0x04, 0x38). The resolution is then determined by accessing the register description of the corresponding imager stored in the database DB. Thus, the database is accessed using the register address of the imager type as a property. An image resolution (horizontal×vertical) of 1920×1080 results as characteristic Ch.

In step d) the appropriate code, e.g., C++ code, is generated and the configuration is performed by executing the code.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for configuring a module for simulating at least one sensor, wherein the module has a sensor simulation and a first data interface of a first type, wherein the sensor simulation is designed and set up to supply synthetic sensor data to a device for executing open- and/or closed-loop tasks via the first data interface of the first type, the method comprising:
a) receiving a record of a data exchange of a real sensor with the device, wherein the data exchange took place via a second data interface of the first type, and/or receiving information about at least one property of the real sensor and/or the second data interface of the first type;
b) reading out the record and/or the information about the at least one property;
c) determining at least one characteristic of the real sensor and/or the second data interface of the first type; and
d) configuring the sensor simulation and/or the first data interface of the first type using the at least one characteristic such that the synthetic sensor data simulate the sensor data of the real sensor.

2. The method according to claim 1, wherein the first and second data interfaces of the first type are designed and set up for data exchange using the same protocol, and wherein the first and second data interfaces of the first type are designed as serializers.

3. The method according to claim 2, wherein the at least one characteristic is determined by reading out the record based on the at least one property of the protocol, the real sensor, and/or the second data interface of the first type.

4. The method according to claim 3, wherein the sensor simulation and/or the first data interface of the first type are configured by writing at least one register of the module, wherein the written content of the register depends on the at least one characteristic, and wherein the selection of the register depends on the at least one property.

5. The method according to claim 1, wherein in method step d) a code or an executable program code and/or a configuration file, is generated which, when executed, carries out the configuration.

6. The method according to claim 1, wherein a database is accessed to determine the at least one characteristic and/or to generate the code, wherein the at least one characteristic is determined depending on a data content provided by the database and/or the code is generated depending on a further data content provided by the database, and wherein the data content provided by the database and/or the further data content depend on the at least one property.

7. The method according to claim 1, wherein, in a method step, a data content is written into the database using the at least one property such that it is suitable to be provided by the database based on the at least one property, and wherein the data content depends in particular on the record read out in step b) and/or the information about the at least one property read out in step b).

8. A device for configuring a module for simulating at least one sensor, wherein the module has hardware and software for a sensor simulation and a first data interface of a first type, wherein the sensor simulation is designed and set up to supply synthetic sensor data to the device for executing open- and/or closed-loop tasks via the first data interface of the first type, wherein the device is set up and designed to receive a record of a data exchange of a real sensor with the device, wherein the data exchange took place via a second data interface of the first type and/or to receive information about at least one property of the real sensor and/or the second data interface of the first type, to read out the record and/or the information about the at least one property, to determine at least one characteristic of the real sensor and/or the second data interface of the first type, and to configure the sensor simulation and/or the first data interface of the first type using the at least one characteristic such that the synthetic sensor data simulate the sensor data of the real sensor.

9. The device for configuring according to claim 8, wherein the device is a control unit and/or a device for simulating a control unit.

10. The device for configuring according to claim 8, wherein the device is designed and set up to generate a code or an executable program code and/or a configuration file, and to perform the configuration by executing the code.

11. The device according to claim 10, wherein the device is designed and set up to access a database to determine the at least one characteristic and/or to generate the code, wherein the device is designed and set up to determine the at least one characteristic depending on a data content provided by the database and/or to generate the code depending on a further data content provided by the database, wherein the data content provided by the database and/or further data content depend on the at least one property.

12. The device according to claim 11, wherein the device has a memory with the database and/or the device has a communication interface for accessing the database.

13. A module for simulating at least one sensor with a device according to claim 8.

14. The module according to claim 13, wherein the synthetic sensor data simulate the sensor data from a camera sensor, a radar sensor, a lidar sensor, an ultrasonic sensor, and/or an infrared sensor.

15. A device for executing open- and/or closed-loop tasks, which comprises the module according to claim 13, or which has a data interface of the second type for receiving synthetic sensor data from the module.
